(19) United States
(12) Patent Application Publication
(10) Pub. No.: US 2024/0413062 A1
(43) Pub. Date: Dec. 12, 2024

(54) PACKAGE STRUCTURE

(71) Applicant: Advanced Semiconductor Engineering, Inc., Kaohsiung (TW)

(72) Inventor: Jen-Hao PAN, Kaohsiung (TW)

(73) Assignee: Advanced Semiconductor Engineering, Inc., Kaohsiung (TW)

(21) Appl. No.: 18/207,088

(22) Filed: Jun. 7, 2023

(51) Int. Cl. H01L 23/498; H01L 23/00; H01L 23/31; H01L 23/49

(52) U.S. Cl. CPC H01L 23/49811; H01L 23/3121; H01L 23/49; H01L 24/45; H01L 24/46; H01L 2224/45005; H01L 2224/46

(57) ABSTRACT

A package structure is provided. The package structure includes a wiring structure, a first element, and a plurality of first wires. The wiring structure has a first recess recessed from a first surface of the wiring structure. The first element is disposed over the first surface of the wiring structure. The first wires are disposed in the first recess and extending in a direction from the wiring structure to the first element. The first wires are configured to reduce an inclination of the first element with respect to the first surface of the wiring structure.

### BACKGROUND

### 1. Technical Field

The present disclosure relates generally to a package structure.

### 2. Description of the Related Art

With the continuous developments of miniaturization of package structures (e.g., package structures including stacked components), pitches between conductive terminals of electronic components in the package structures have been decreased toward 20-30 μm or even smaller. In current package structures, soldering materials (e.g., solder pastes) are used to bond conductive terminals of electronic components. However, the soldering materials, after being reflowed, may cause undesired bridging issues between conductive terminals that are not supposed to connect to each other.

### SUMMARY

In one or more arrangements, a package structure includes a wiring structure, a first element, and a plurality of first wires. The wiring structure has a first recess recessed from a first surface of the wiring structure. The first element is disposed over the first surface of the wiring structure. The first wires are disposed in the first recess and extending in a direction from the wiring structure to the first element. The first wires are configured to reduce an inclination of the first element with respect to the first surface of the wiring structure.

In one or more arrangements, a package structure includes a wiring structure, a wire bond connection, and a plurality of wires. The wire bond connection is disposed over the wiring structure. The wires connect the wiring structure to a first surface of the wire bond connection and are configured to define a non-planar profile of the first surface of the wire bond connection.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a package structure in accordance with some arrangements of the present disclosure.

FIG. 1A is a cross-section of a portion of a package structure in accordance with some arrangements of the present disclosure.

FIG. 1B is a cross-section of a portion of a package structure in accordance with some arrangements of the present disclosure.

FIG. 1C is a cross-section of a portion of a package structure in accordance with some arrangements of the present disclosure.

FIG. 2 is a cross-section of a package structure in accordance with some arrangements of the present disclosure.

FIG. 2A is a cross-section of a portion of a package structure in accordance with some arrangements of the present disclosure.

FIG. 3A is a cross-section of a portion of a package structure in accordance with some arrangements of the present disclosure.

FIG. 3B is a cross-section of a portion of a package structure in accordance with some arrangements of the present disclosure.

FIG. 4A is a cross-section of a portion of a package structure in accordance with some arrangements of the present disclosure.

FIG. 4B is a cross-section of a portion of a package structure in accordance with some arrangements of the present disclosure.

FIG. 5A is a top view of a portion of a package structure in accordance with some arrangements of the present disclosure.

FIG. 5B is a top view of a portion of a package structure in accordance with some arrangements of the present disclosure.

FIG. 5C is a top view of a portion of a package structure in accordance with some arrangements of the present disclosure.

FIG. 6A, FIG. 6B, FIG. 6C, FIG. 6D, and FIG. 6E illustrate various stages of an example of a method for manufacturing a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

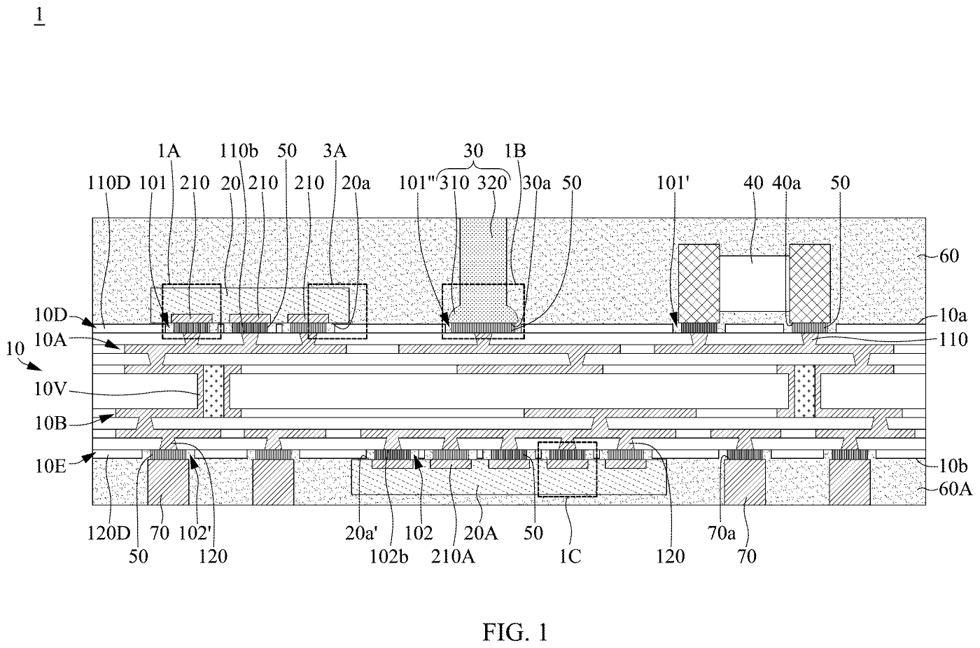

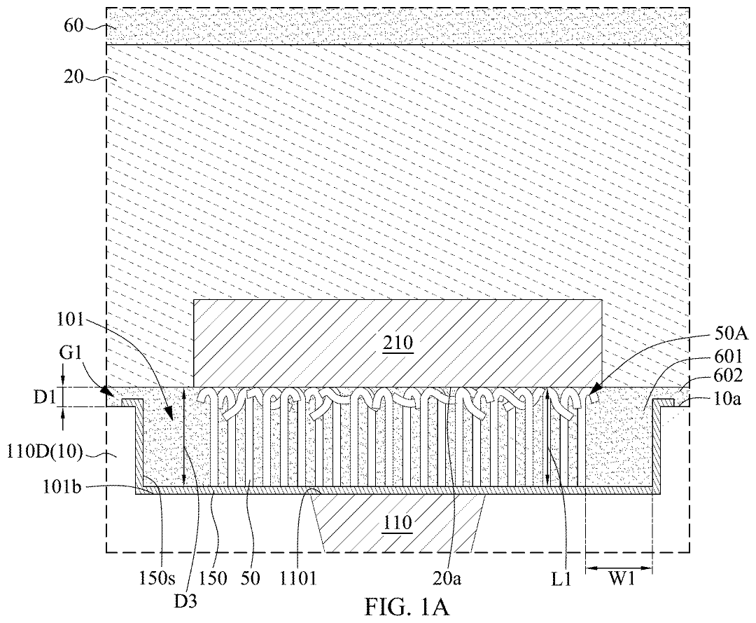

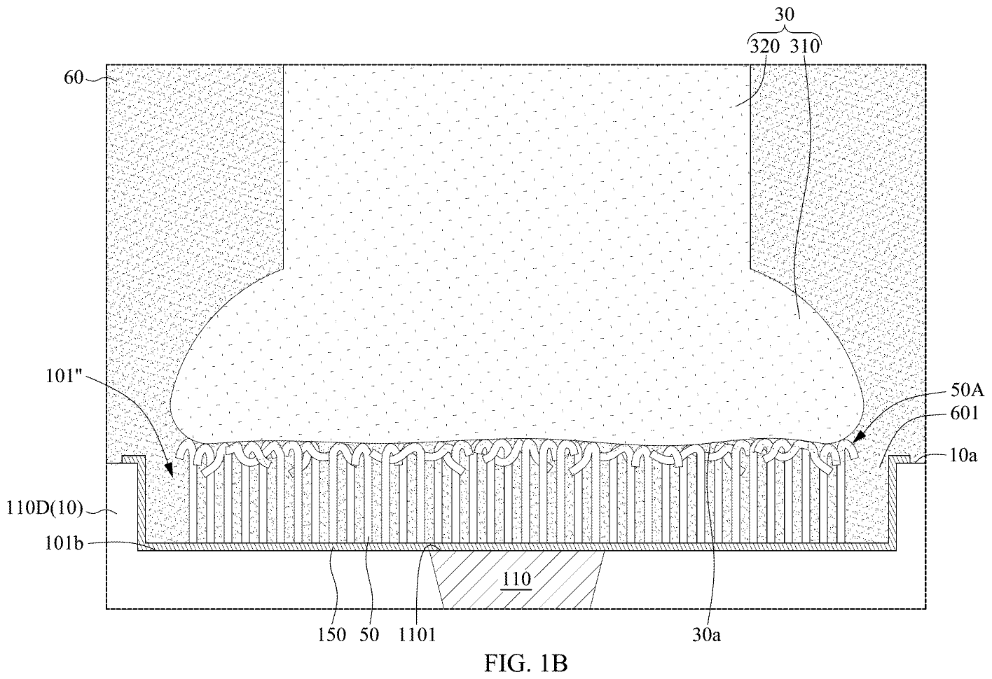

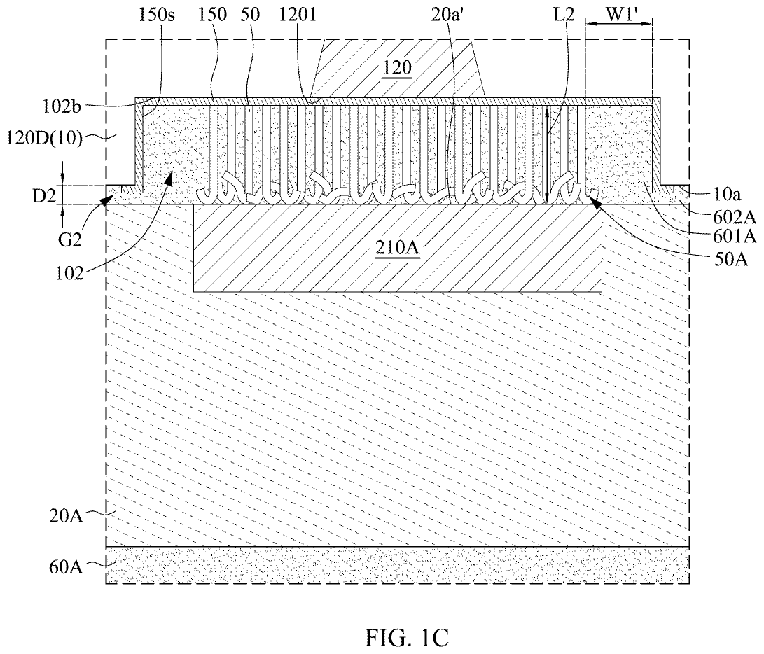

FIG. 1 is a cross-section of a package structure 1 in accordance with some arrangements of the present disclosure. The package structure 1 may include a wiring structure 10, elements, wires 50, and encapsulants 60 and 60A. The elements may be or include conductive elements (e.g., electronic components 20, 20A and 40, a bonding wire element 30, and conductive pillars 70). It should be noted that the numbers of the electronic components 20, 20A and 40, the bonding wire element 30, the wires 50, the encapsulants 60 and 60A, the conductive pillars 70, and/or other components may vary according to actual applications and are not limited thereto.

The wiring structure 10 may include, for example, a printed circuit board, such as a paper-based copper foil laminate, a composite copper foil laminate, or a polymer-impregnated glass-fiber-based copper foil laminate. The wiring structure 10 may include an interconnection structure, which may include such as a plurality of conductive traces and/or a plurality of conductive vias. The interconnection structure may include a redistribution layer (RDL) and/or a grounding element. In some arrangements, the wiring structure 10 may include a substrate, such as an organic substrate or a leadframe. The wiring structure 10 may be referred to as a carrier, for example, a conductive carrier.

In some arrangements, the wiring structure 10 may include a multi-layer substrate which includes a core layer 10C, conductive structures 10A and 10B disposed on opposite surfaces (e.g., an upper surface and a bottom surface) of the core layer 10C, and dielectric structures 10D and 10E disposed on opposite surfaces of the core layer 10C. The conductive structure 10A may include a plurality of traces, vias, and/or pads formed or disposed in the dielectric structure 10D, and the conductive structure 10B may include a plurality of traces, vias, and/or pads formed or disposed in the dielectric structure 10E. The wiring structure 10 may include one or more conductive vias 10V penetrating the core layer 10C to electrically connect the conductive structures 10A and 10B. The conductive via 10V may include a conductive liner connected to the conductive structures 10A and 10B and an insulating filler covered or surrounded by the conductive liner. The wiring structure 10 may be free of a solder resist, solder paste, or other soldering materials on the upper surface and/or the bottom surface of the wiring structure 10.

In some arrangements, the wiring structure 10 has a surface 10a (also referred to as an upper surface or a top surface) and a surface 10b (also referred to as a lower surface or a bottom surface) opposite to the surface 10a. In some arrangements, the wiring structure 10 has one or more recesses (e.g., recesses 101, 101′, and 101″) recessed from the surface 10a. In some arrangements, bottom surfaces of the recesses 101, 101′, and 101″ are recessed with respect to the surface 10a. In some arrangements, the wiring structure 10 further has one or more recesses (e.g., recesses 102 and 102′) recessed from the surface 10b. In some arrangements, bottom surfaces of the recesses 102 and 102′ are recessed with respect to the surface 10b.

In some arrangements, the wiring structure 10 (or the dielectric structure 10D) includes a dielectric layer 110D defining the one or more recesses (e.g., the recesses 101, 101′, and 101″) recessed from the surface 10a. In some arrangements, the wiring structure 10 (or the conductive structure 10A) includes one or more conductive pads (e.g., conductive pads 110) in proximity to or adjacent to the surface 10a of the wiring structure 10. In some arrangements, the conductive pad 110 is adjacent to the recess (e.g., the recesses 101, 101′, and/or 101″). In some arrangements, the conductive pad 110 is exposed to the recess (e.g., the recesses 101, 101′, and/or 101″). In some arrangements, the conductive pad 110 penetrates an opening of the dielectric layer 110D, and an upper surface 1101 of the conductive pad 110 is substantially aligned with a bottom surface 101b of the recess (e.g., the recesses 101, 101′, and/or 101″) defined by the dielectric layer 110D.

In some arrangements, the wiring structure 10 (or the dielectric structure 10E) includes a dielectric layer 120D defining the one or more recesses (e.g., the recesses 102 and 102′) recessed from the surface 10b. In some arrangements, the wiring structure 10 (or the conductive structure 10B) includes one or more conductive pads (e.g., conductive pads 120) in proximity to or adjacent to the surface 10b of the wiring structure 10. In some arrangements, the conductive pad 120 is adjacent to the recess (e.g., the recesses 102 and 102′). In some arrangements, the conductive pad 120 is exposed to the recess (e.g., the recesses 102 and 102′). In some arrangements, the conductive pad 120 penetrates an opening of the dielectric layer 110E, and an upper surface 1201 of the conductive pad 120 is substantially aligned with a bottom surface 102b of the recess (e.g., the recesses 102 and 102′) defined by the dielectric layer 110E.

The elements or conductive elements may include one or more active devices, one or more passive devices, one or more bonding wire elements, one or more conductive pillars, or a combination thereof. For example, the conductive elements may include electronic components 20, 20A and 40, a bonding wire element 30 (also referred to as “a wire bond” or “a wire bond connection”), and conductive pillars 70. In some arrangements, some of the conductive elements (e.g., the electronic components 20 and 40 and the bonding wire element 30) are disposed over the surface 10a, and some of the conductive elements (e.g., the electronic component 20A and the conductive pillars 70) are disposed over the surface 10b.

In some arrangements, the electronic component 20 is disposed over the surface 10a of the wiring structure 10. In some arrangements, the electronic component 20 has a surface 20a facing the wiring structure 10. The surface 20a may be an active surface of the electronic component 20. In some arrangements, the electronic component 20 includes at least one conductive pad 210 adjacent to and exposed from the surface 20a. In some arrangements, a pitch between the conductive pads 210 is equal to or less than about 30 μm, for example, from about 20 μm to about 30 μm, or less than about 20 μm. The electronic component 20 may be a chip or a die including a semiconductor substrate, one or more integrated circuit (IC) devices and one or more overlying interconnection structures therein. The IC devices may include active devices such as transistors and/or passive devices such as resistors, capacitors, inductors, or a combination thereof. For example, the electronic component 20 may include a system on chip (SoC). For example, the electronic component 20 may include a radiofrequency IC (RFIC), an application-specific IC (ASIC), a central processing unit (CPU), a microprocessor unit (MPU), a graphics processing unit (GPU), a microcontroller unit (MCU), a field-programmable gate array (FPGA), or another type of IC.

In some arrangements, the electronic component 20A is disposed over the surface 10b of the wiring structure 10. In some arrangements, the electronic component 20A has a surface 20a′ facing the wiring structure 10. The surface 20a′ may be an active surface of the electronic component 20A. In some arrangements, the electronic component 20A includes at least one conductive pad 210A adjacent to and exposed from the surface 20a′. In some arrangements, a pitch between the conductive pads 210A is equal to or less than about 30 μm, for example, from about 20 μm to about 30 μm, or less than about 20 μm. The electronic component 20A may be a chip or a die including a semiconductor substrate, one or more IC devices and one or more overlying interconnection structures therein. The IC devices may include active devices such as transistors and/or passive devices such as resistors, capacitors, inductors, or a combination thereof. For example, the electronic component 20A may include a SoC. For example, the electronic component 20A may include a RFIC, an ASIC, a CPU, a MPU, a GPU, a MCU, a FPGA, or another type of IC.

In some arrangements, the bonding wire element 30 is disposed over the surface 10a of the wiring structure 10. In some arrangements, the bonding wire element 30 has a surface 30a facing the wiring structure 10. In some arrangements, the bonding wire element 30 includes a ball bond 310 and a conductive wire 320 (or a bonding wire) connected to the ball bond 310. In some embodiments, the ball bond 310 has the surface 30a. In some arrangements, the bonding wire element 30 is or includes a shielding element.

In some arrangements, the electronic component 40 is disposed over the surface 10a of the wiring structure 10. In some arrangements, the electronic component 40 has a surface 40a facing the wiring structure 10. The electronic component 40 may be a chip or a die including a semiconductor substrate, one or more IC devices and one or more overlying interconnection structures therein. The IC devices may include active devices such as transistors and/or passive devices such as resistors, capacitors, inductors, or a combination thereof.

In some arrangements, the conductive pillar 70 is disposed over the surface 10b of the wiring structure 10. In some arrangements, the conductive pillar 70 has a surface 70a facing the wiring structure 10.

In some arrangements, the wires 50 are disposed at least partially in the recess (e.g., the recesses 101, 101′, and/or 101″), electrically connecting the wiring structure 10 to one or more conductive elements (e.g., the electronic components 20 and 40 and the bonding wire element 30), and configured to support the one or more conductive elements (e.g., the electronic components 20 and 40 and the bonding wire element 30). In some arrangements, the wires 50 extend in a direction from the wiring structure to the one or more conductive elements (e.g., the electronic components 20 and 40 and the bonding wire element 30). In some arrangements, the wires 50 are configured to reduce an inclination of the element (e.g., the electronic components 20 and 40 and the bonding wire element 30) with respect to the surface 10a of the wiring structure 10. In some arrangements, the wires 50 are between the wiring structure 10 and the active surface 20a of the electronic component 20. In some arrangements, the wires 50 are between the wiring structure 10 and the surface 30a of the bonding wire element 30. In some arrangements, the wires 50 are between the wiring structure 10 and the surface 40a of the electronic component 40. In some arrangements, the wires 50 are nanowires. In some arrangements, the wires 50 are conductive nanowires.

In some arrangements, a projection of the wires 50 on a bottom surface (e.g., bottom surface 101b) of the recess (e.g., the recesses 101, 101′, and/or 101″) overlaps the dielectric layer 110D. In some arrangements, the wires 50 are disposed over a portion of the dielectric layer 110D within the recess (e.g., the recesses 101, 101′, and/or 101″). In some arrangements, the conductive pad 110 is electrically connected to the wires 50. In some arrangements, an area of the conductive pad 110 is less than an area of the projection of the wires 50. In some arrangements, the conductive pad 110 is entirely within the projection of the wires 50 on the bottom surface (e.g., the bottom surface 101b) of the recess (e.g., the recesses 101, 101′, and/or 101″). In some arrangements, the wires 50 electrically connect the conductive pad 110 to the surface (e.g., the surface 20a, 40a, and/or 30a) of the conductive element (e.g., the electronic component 20, the electronic component 40, and/or the bonding wire element 30).

In some arrangements, the wires 50 are disposed at least partially in the recess (e.g., the recesses 102 and 102′), electrically connecting the wiring structure 10 to one or more conductive elements (e.g., the electronic component 20A and the conductive pillar 70), and configured to support the one or more conductive elements (e.g., the electronic component 20A and the conductive pillar 70). In some arrangements, the wires 50 are between the wiring structure 10 and the active surface 20a′ of the electronic component 20A. In some arrangements, the wires 50 are between the wiring structure 10 and the surface 70a of the conductive pillar 70.

In some arrangements, a projection of the wires 50 on a bottom surface (e.g., bottom surface 102b) of the recess (e.g., the recesses 102 and/or 102′) overlaps the dielectric layer 120D. In some arrangements, the wires 50 are disposed over a portion of the dielectric layer 120D within the recess (e.g., the recesses 102 and/or 102′). In some arrangements, the conductive pad 120 is electrically connected to the wires 50. In some arrangements, an area of the conductive pad 120 is less than an area of the projection of the wires 50. In some arrangements, the conductive pad 120 is entirely within the projection of the wires 50 on the bottom surface (e.g., the bottom surface 102b) of the recess (e.g., the recesses 102 and/or 102′). In some arrangements, the wires 50 electrically connect the conductive pad 120 to the surface (e.g., the surface 20a′ and/or 70a) of the conductive element (e.g., the electronic component 20A and/or the conductive pillar 70).

The encapsulant 60 may encapsulate the electronic components 20 and 40, the bonding wire element 30, and the wires 50 in proximity to or adjacent to the surface 10a of the wiring structure 10. In some arrangements, the encapsulant 60 encapsulates at least a portion of the wires 50. In some arrangements, the encapsulant 60 is a monolithic layer. In some arrangements, the encapsulant 60 is a monolithic encapsulant. The encapsulant 60 may include an epoxy resin having fillers, a molding compound (e.g., an epoxy molding compound or other molding compound), polyimide, a phenolic compound or material, a material with a silicone dispersed therein, or a combination thereof.

The encapsulant 60A may encapsulate the electronic component 20A, the conductive pillars 70, and the wires 50 in proximity to or adjacent to the surface 10b of the wiring structure 10. In some arrangements, the encapsulant 60A encapsulates at least a portion of the wires 50. In some arrangements, the encapsulant 60A is a monolithic layer. In some arrangements, the encapsulant 60A is a monolithic encapsulant. The encapsulant 60A may include an epoxy resin having fillers, a molding compound (e.g., an epoxy molding compound or other molding compound), polyimide, a phenolic compound or material, a material with a silicone dispersed therein, or a combination thereof. In some arrangements, the encapsulant 60 is spaced apart from the encapsulant 60A by the wiring structure 10.

FIG. 1A is a cross-section of a portion of a package structure in accordance with some arrangements of the present disclosure. In some arrangements, FIG. 1A is a cross-section of a portion 1A of the package structure 1 in FIG. 1 in accordance with some arrangements of the present disclosure.

In some arrangements, an upper surface (e.g., the surface 10a) of the wiring structure 10 is spaced apart from the surface 20a of the electronic component 20 by a gap G1, and a distance D1 of the gap G1 is less than a length L1 of the wires 50. In some arrangements, the distance D1 is less than a depth D3 of the recess 101.

In some arrangements, the encapsulant 60 includes an extension 601 that is further disposed within the recess (e.g., the recesses 101, 101′, and/or 101″). In some arrangements, the extension 601 extends into the recess (e.g., the recesses 101, 101′, and/or 101″). In some arrangements, the extension 601 extends between the wires 50. In some embodiments, the encapsulant 60 includes a portion 602 that is filled in the gap G1.

In some arrangements, the package structure 1 further includes a seed layer 150 between the dielectric layer 110D and the wires 50. In some arrangements, the seed layer 150 is disposed on the conductive pad 110 and the dielectric layer 110D. In some arrangements, the seed layer 150 covers the bottom surface 101b of the recess 101, inner sidewalls of the recess 101, and a portion of the surface 10a of the wiring structure 10. In some arrangements, referring to FIGS. 1 and 1A, the package structure 1 may include a plurality of seed layers 150 each disposed in one of the recesses 101, 101′ and 101″.

In some arrangements, the wires 50 include a curved portion 50A adjacent to the electronic component 20. In some arrangements, the curved portion 50A includes a plurality of curved ends of the wires 50. In some embodiments, one of the curved ends of the wires 50 may contact another wire 50. In some arrangements, the curved portion 50A contacts the element (e.g., the electronic components 20 and 40 and the bonding wire element 30).

In some arrangements, a width W1 of the extension 601 is equal to or greater than about 3 μm. In some arrangements, a gap between the wires 50 and an inner lateral surface 150s of the seed layer 150 may have a distance (e.g., the width W1) that is equal to or greater than about 3 μm. In some arrangements, the width W1 is greater than a distance between adjacent wires 50.

FIG. 1B is a cross-section of a portion of a package structure in accordance with some arrangements of the present disclosure. In some arrangements, FIG. 1B is a cross-section of a portion 1B of the package structure 1 in FIG. 1 in accordance with some arrangements of the present disclosure.

In some arrangements, the surface 30a of the ball bond 310 of the bonding wire element 30 may be or include a non-planar surface. In some arrangements, the surface 30a of the ball bond 310 further contacts the encapsulant 60. In some arrangements, the surface 30a of the ball bond 310 is spaced apart from the surface 10a of the wiring structure by a portion of the encapsulant 60.

FIG. 1C is a cross-section of a portion of a package structure in accordance with some arrangements of the present disclosure. In some arrangements, FIG. 1C is a cross-section of a portion 1C of the package structure 1 in FIG. 1 in accordance with some arrangements of the present disclosure.

In some arrangements, a bottom surface (e.g., the surface 10b) of the wiring structure 10 is spaced apart from the surface 20a′ of the electronic component 20 by a gap G2, and a distance D2 of the gap G2 is less than a length L2 of the wires 50.

In some arrangements, the encapsulant 60A includes an extension 601A that is further disposed within the recess (e.g., the recesses 102 and/or 102′). In some embodiments, the encapsulant 60A includes a portion 602A that is filled in the gap G2.

In some arrangements, the package structure 1 further includes a seed layer 150 between the dielectric layer 120D and the wires 50. In some arrangements, the seed layer 150 is disposed on the conductive pad 120 and the dielectric layer 120D. In some arrangements, the seed layer 150 covers the bottom surface 102b of the recess 102, inner sidewalls of the recess 102, and a portion of the surface 10b of the wiring structure 10. In some arrangements, referring to FIGS. 1 and 1C, the package structure 1 may include a plurality of seed layers 150 each disposed in one of the recesses 102 and 102′.

In some arrangements, the wires 50 include a curved portion 50A adjacent to the electronic component 20A. In some arrangements, the curved portion 50A includes a plurality of curved ends of the wires 50. In some embodiments, one of the curved ends of the wires 50 may contact another wire 50.

In some arrangements, a width W1′ of the extension 601A is equal to or greater than about 3 μm. In some arrangements, a gap between the wires 50 and an inner lateral surface 150s of the seed layer 150 may have a distance (e.g., the width W1′) that is equal to or greater than about 3 μm. In some arrangements, the width W1′ is greater than a distance between adjacent wires 50.

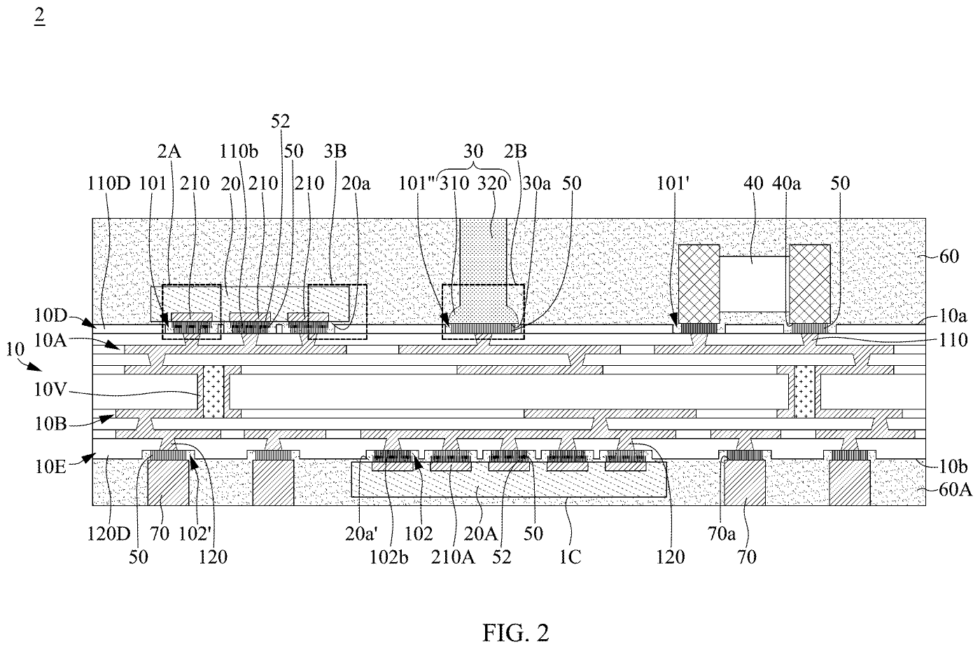

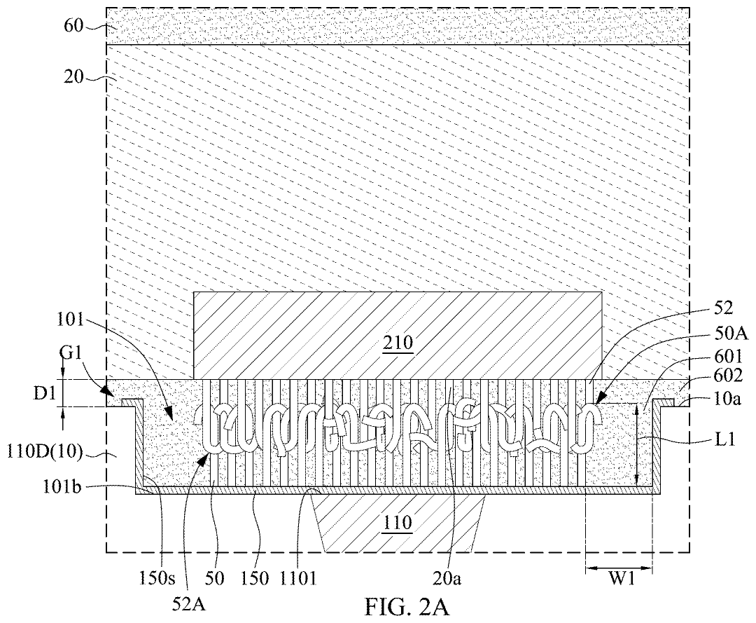

FIG. 2 is a cross-section of a package structure 2 in accordance with some arrangements of the present disclosure. The package structure 2 illustrated in FIG. 2 is similar to the package structure 1 in FIG. 1, and the differences therebetween are described as follows.

In some arrangements, the electronic component 20 includes a plurality of wires 52 contacting the wires 50 and electrically connecting the wiring structure 10 to the electronic component 20. In some arrangements, the wires 52 are partially within the recess 101. In some arrangements, the electronic component 20 does not include a conductive pad (e.g., the conductive pad 210 illustrated in FIG. 1). In some arrangements, the wires 52 are nanowires. In some arrangements, the wires 52 are conductive nanowires.

In some arrangements, the electronic component 20A includes a plurality of wires 52 contacting the wires 50 and electrically connecting the wiring structure 10 to the electronic component 20A. In some arrangements, the wires 52 are partially within the recess 102. In some arrangements, the electronic component 20A does not include a conductive pad (e.g., the conductive pad 210A illustrated in FIG. 1).

In some arrangements, the encapsulant 60 encapsulates the electronic components 20 and 40, the bonding wire element 30, and the wires 50 and 52. In some embodiments, the encapsulant 60 contacts the wires 50 and 52.

In some arrangements, the encapsulant 60A encapsulates the electronic component 20A, the conductive pillars 70, and the wires 50 and 52. In some embodiments, the encapsulant 60A contacts the wires 50 and 52.

FIG. 2A is a cross-section of a portion of a package structure in accordance with some arrangements of the present disclosure. In some arrangements, FIG. 2A is a cross-section of a portion 2A of the package structure 2 in FIG. 2 in accordance with some arrangements of the present disclosure.

In some arrangements, the wires 50 include a curved portion 50A, and the wires 52 include a curved portion 52A adjacent to the curved portion 50A of the wires 50. In some embodiments, the curved portion 50A contacts the curved portion 52A. In some arrangements, the curved portions 50A and 52A are at least partially within the recess 101. In some embodiments, the curved portion 50A includes at least an end portion of a wire 50, and the curved portion 52A includes at least an end portion of a wire 52 that contacts the end segment of the wire 50. In some arrangements, a sidewall of the end portion of the wire 50 contacts a sidewall of the end portion of the wire 52. In some arrangements a curved portion of the wire 50 crosses over one or more wires 52. In some arrangements a curved portion of the wire 52 crosses over one or more wires 50.

According to some arrangements of the present disclosure, the conductive pads 210 and/or 210A having a relatively small pitch are connected to the wiring structure 10 through the wires 50 rather than soldering materials (e.g., solder bumps or solder pastes), and therefore, solder bridge issues resulted from one or more reflow operations performed on the soldering materials in the bonding process can be mitigated or prevented. That is, while solder bumps or solder pastes may melt and undesirably connect conductive pads and/or terminals that are not supposed to be connected, wires (e.g., conductive nanowires) can have a relatively small size and connect conductive terminals without performing any reflow operations. Accordingly, wires (e.g., conductive nanowires) do not need to melt in order to bond or connect the conductive pads, and thus connection of conductive pads 210 having a relatively small pitch to an external structure (e.g., the wiring structure 10) can be achieved without short circuit issues raised, thus the yield can be increased.

Furthermore, solder bumps or solder pastes may have relatively large heights compared to the wires, and thus according to some arrangements of the present disclosure, bonding through wires can further reduce the overall thickness of the package structure. Moreover, according to some arrangements of the present disclosure, solder bumps or solder pastes are not required for bonding conductive elements to the wiring structure, and thus reflow operations are not required for bonding conductive elements to the wiring structure. Therefore, the order in which conductive elements are bonded to opposite sides of the wiring structure can be disregarded, since bonding structures formed of wires do not melt under thermal operations. Accordingly, the flexibility of the manufacturing process is increased, and the yield can be increased as well.

In addition, according to some arrangements of the present disclosure, the wires are at least partially encapsulated by an encapsulant. Therefore, the structural strength of the wires can be increased, and the relative position of the wires to the elements (e.g., the conductive elements and the wiring structure) that are connected to each other by the wires can be fixed. Accordingly, the yield can be significantly increased.

Moreover, according to some arrangements of the present disclosure, the wires are at least partially disposed within the recess of the wiring structure. Therefore, the bonding structure formed of the wires can be further protected by the wiring structure, and the overall thickness of the package structure can be reduced. In addition, according to some arrangements of the present disclosure, portions of the encapsulant are further filled in the recess and at least partially encapsulating the wires, and thus less air remains in the recess. Therefore, despite that multiple thermal operations may be performed in the manufacturing process, the relatively less remained air is not sufficient to create an expansion volume or expansion amount that can break or damage the package structure. In addition, voids formed of remained air are reduced, and thus the resistance of the bonding structure formed of the wires can be prevented from being adversely affected by the voids.

Furthermore, according to some arrangements of the present disclosure, the wires are disposed or formed not only over the conductive pad but also over the dielectric layer, such that the wires occupy a relatively large area within the recess of the wiring structure. Therefore, with such relatively large area, the supporting strength provided by the wires is relatively uniform, and thus the wires can provide relatively sufficient supporting strength for the conductive elements (e.g., the electronic components, the bonding wire element, the conductive pillars, and etc.) there above.

Moreover, according to some arrangements of the present disclosure, a gap having a distance equal to or greater than about 3 μm may be present or formed between the wires and an inner lateral surface of the seed layer within the recess. Since the wires can provide relatively uniform and sufficient supporting strength for the conductive elements there above, the gap may be relatively large to facilitate filling the encapsulant into the recess through the gap in the manufacturing process, and the gap does not adversely affect the supporting strength.

In addition, according to some arrangements of the present disclosure, the wires 50 are connected to the wires 52 of the electronic component 20 and/or 20A, and the sidewalls of the wires 50 directly contact the sidewalls of the wires 52. Therefore, with such tangling arrangements of the wires 50 and 52, the relative position of the wires 50 to the wires 52 can be fixed, and thereby the relative position of the electronic component 20 and/or 20A to the wiring structure 10 can be fixed. In addition, the tangling arrangements of the wires 50 and 52 can further provide a supporting strength in a vertical direction (i.e., in a direction from the wiring structure 10 toward the electronic component 20 and/or 20A), such that the potential warpage of the wiring structure 10 can be further reduced by the supporting strength provided by the tangled wires 50 and 52. Therefore, warpage of the package structure can be further mitigated or reduced.

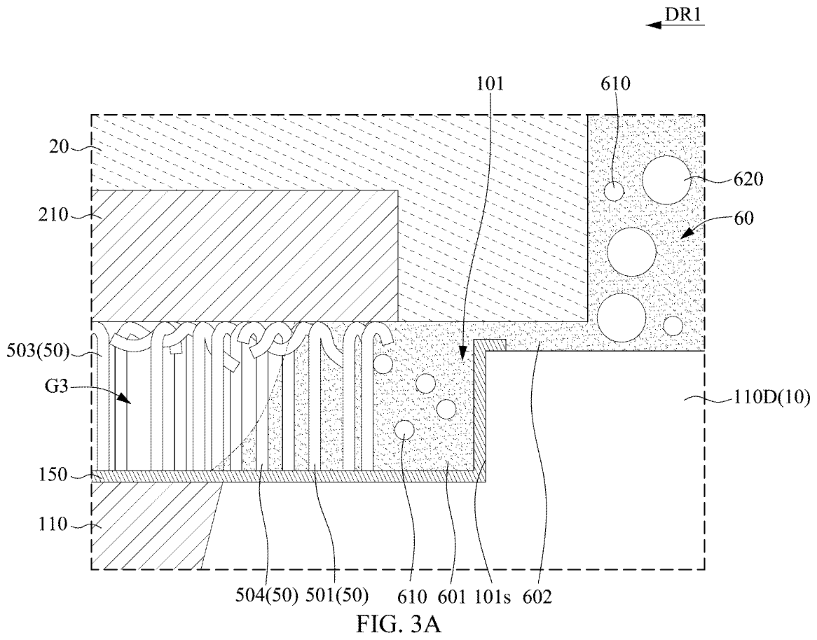

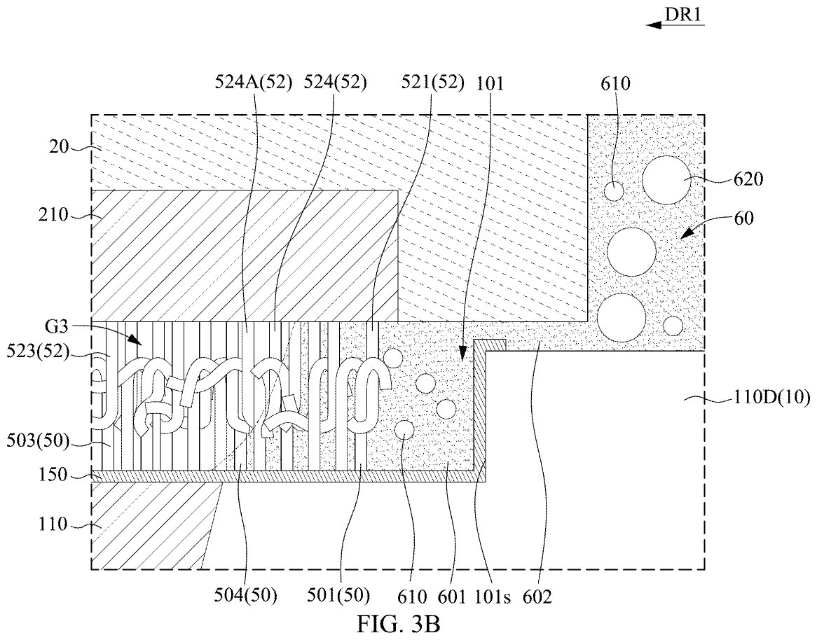

FIG. 3A is a cross-section of a portion of a package structure in accordance with some arrangements of the present disclosure. In some arrangements, FIG. 3A is a cross-section of a portion 3A of the package structure 1 in FIG. 1 in accordance with some arrangements of the present disclosure.

In some arrangements, the wires 50 include one or more wires 501 contacting the encapsulant 60. In some arrangements, the wires 50 further include one or more wires 503 spaced apart from the encapsulant 60 by an air gap G3. In some arrangements, a thickness of the encapsulant 60 decreases in a direction DR1 from the wires 501 toward the wires 503. In some arrangements, the wires 50 further include one or more wires 504 between the wires 501 and the wires 503. In some arrangements, the wire 504 may include a portion (also referred to as a first portion) contacting the encapsulant 60 and a portion (also referred to as a second portion) exposed to the air gap G3. In some arrangements, a portion of the surface 20a of the electronic component 20 is exposed to the air gap G3. In some arrangements, a portion of the seed layer 150 is exposed to the air gap G3. In some arrangements, the air gap G3 is spaced apart from an inner sidewall 101s by a portion of the seed layer 150 and the extension 601 of the encapsulant 60.

In some embodiments, the encapsulant 60 includes fillers 610 and 620. In some arrangements, the filler 610 is disposed adjacent to the inner sidewall 101s of the recess 101. In some arrangements, the filler 610 contacts at least a sidewall of the wires 50 (or the wires 501). In some embodiments, the extension 601 of the encapsulant 60 includes the fillers 610. In some embodiments, the filler 610 is disposed in the recess 101. In some embodiments, the filler 610 mat be further disposed outside of the recess 101. In some embodiments, the filler 620 is disposed outside of the recess 101. In some embodiments, a size of the filler 610 is less than a size of the filler 620. In some embodiments, a size of the filler 610 is less than the distance D1 of the gap G1.

FIG. 3B is a cross-section of a portion of a package structure in accordance with some arrangements of the present disclosure. In some arrangements, FIG. 3B is a cross-section of a portion 3B of the package structure 2 in FIG. 2 in accordance with some arrangements of the present disclosure.

In some arrangements, the wires 52 include one or more wires 521 contacting the encapsulant 60. In some arrangements, the wires 521 contact the wires 501. In some arrangements, the wires 50 further include one or more wires 523 spaced apart from the encapsulant 60 by the air gap G3. In some arrangements, the wires 523 contact the wires 503. In some arrangements, the wires 52 further include one or more wires 524 and one or more wires 524A between the wires 521 and the wires 523. In some arrangements, the wires 524 contact the wires 504 and the encapsulant 60. In some arrangements, the wires 524A contact the wires 504 and are spaced apart from the encapsulant 60 by the air gap G3.

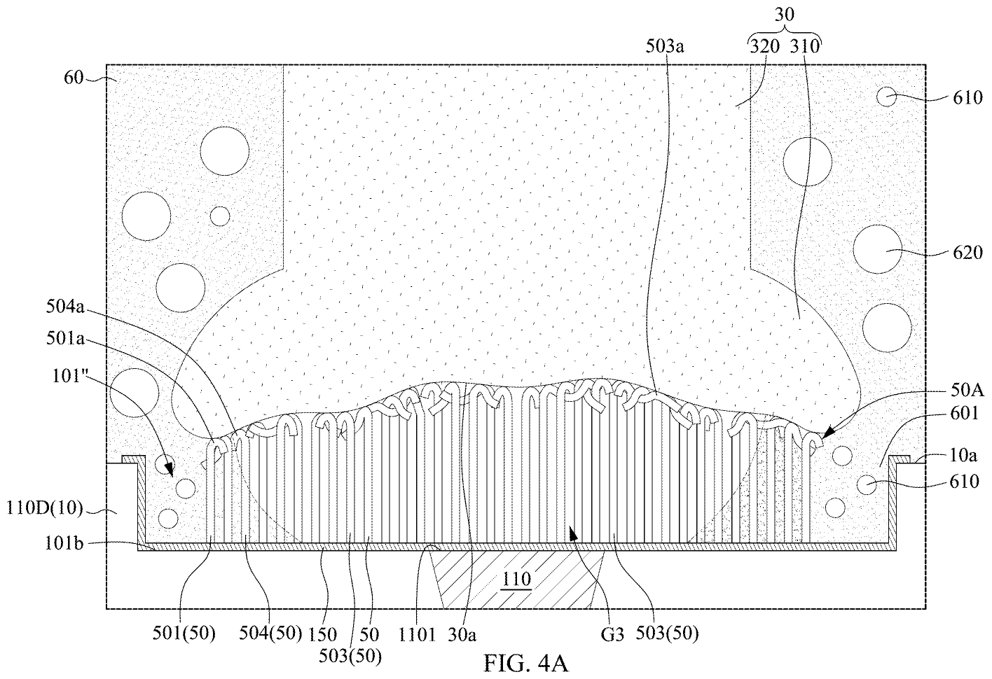

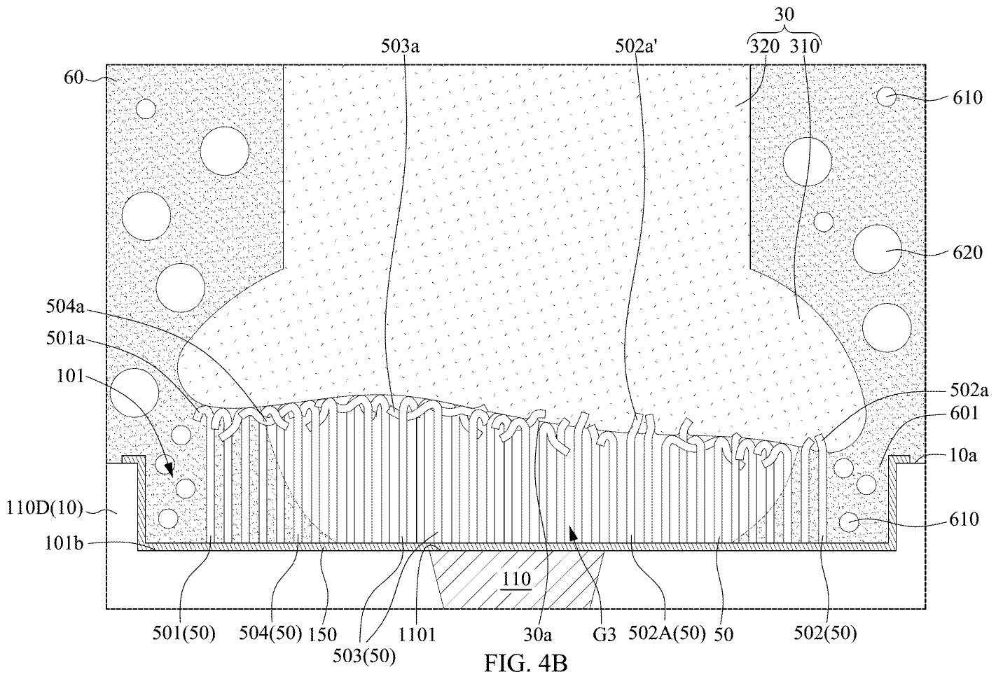

FIG. 4A is a cross-section of a portion of a package structure in accordance with some arrangements of the present disclosure. In some arrangements, FIG. 4A is a cross-section of a portion 1B of the package structure 1 in FIG. 1 or a portion 2B of the package structure 2 in FIG. 2 in accordance with some arrangements of the present disclosure.

In some arrangements, the wires 50 connect the wiring structure 10 to the surface 30a of the bonding wire element 30 and configured to define a non-planar profile of the surface 30a. In some arrangements, the surface 30a includes a wavy surface portion. In some arrangements, the conductive wire 320 is connected to the wires 50 through the ball bond 310, and the ball bond 310 has the non-planar profile. In some arrangements, the non-planar profile of the surface 30a is at least partially exposed to the air gap G3.

In some arrangements, the wires 50 include wires 501, 503, and 504, and at least one of the wires has a curved end (e.g., curved ends 501a, 503a, and 504a) contacting the bonding wire element 30. In some arrangements, the wires 501 are encapsulated by the extension 601 of the encapsulant 60. In some arrangements, the curved ends 501a are encapsulated by the extension 601 of the encapsulant 60. In some arrangements, the wires 504 are partially encapsulated by the extension 601 of the encapsulant 60. In some arrangements, the curved ends 504a are at least partially encapsulated by the extension 601 of the encapsulant 60. In some arrangements, the wires 503 are exposed to the air gap G3 and spaced apart from the encapsulant 60. In some arrangements, the curved ends 503a are exposed to the air gap G3 and spaced apart from the encapsulant 60. In some arrangements, at least two of the wires 501, 503, and 504 have different lengths (or heights).

FIG. 4B is a cross-section of a portion of a package structure in accordance with some arrangements of the present disclosure. In some arrangements, FIG. 4B is a cross-section of a portion 1B of the package structure 1 in FIG. 1 or a portion 2B of the package structure 2 in FIG. 2 in accordance with some arrangements of the present disclosure.

In some arrangements, the wires 50 further include wires 502 and 502A inserted into the bonding wire element 30. In some arrangements, the wires 502 are partially encapsulated or covered by the encapsulant 60, and end portions 502a of the wires 502 are embedded in the ball bond 310 of the bonding wire element 30. In some arrangements, the wires 502A are partially exposed to the air gap G2, and end portions 502a′ of the wires 502A are embedded in the ball bond 310 of the bonding wire element 30. In some arrangements, the non-planar profile of the surface 30a is inclined with respect to the surface 10a of the wiring structure 10.

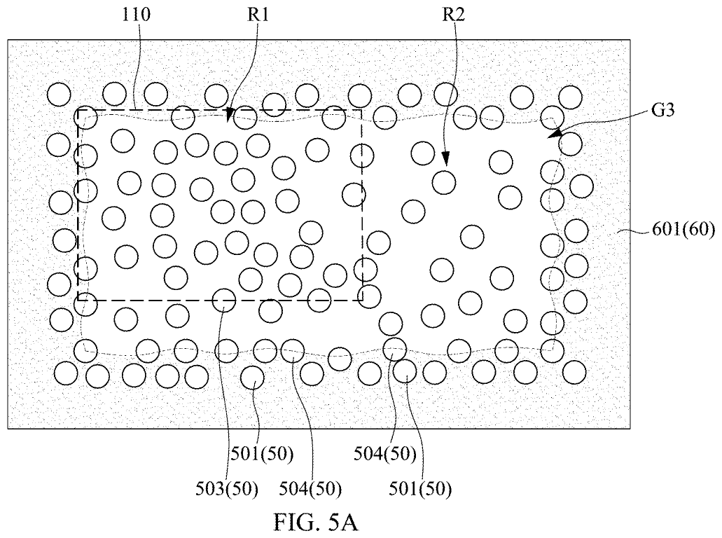

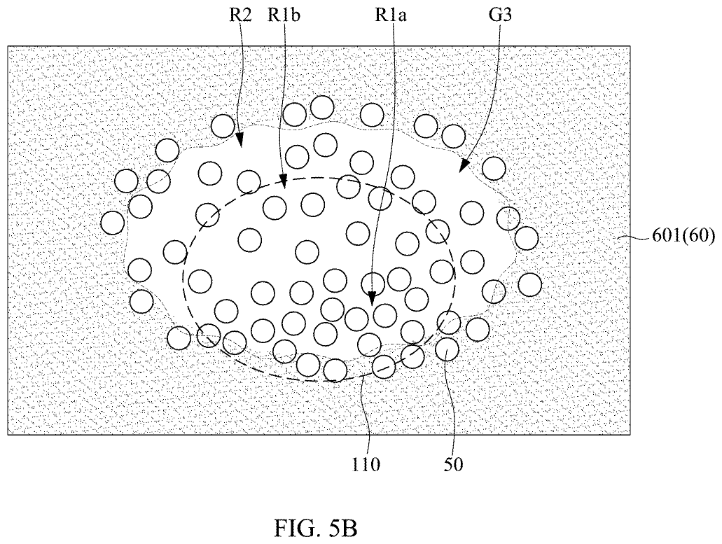

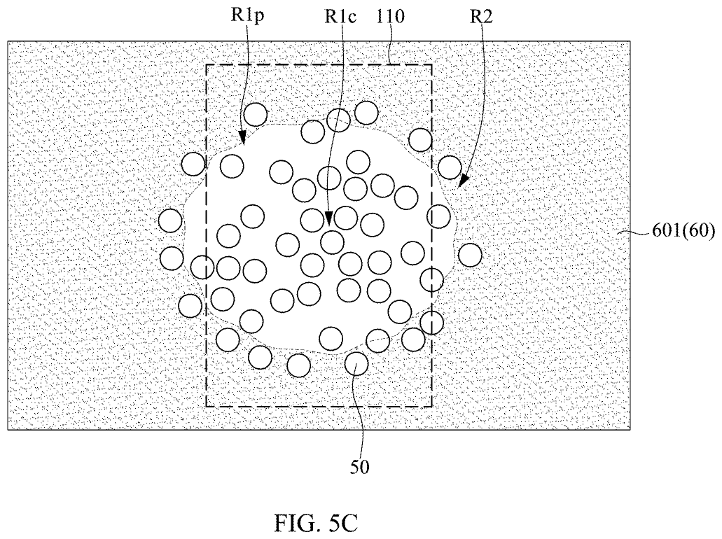

FIG. 5A is a top view of a portion of a package structure in accordance with some arrangements of the present disclosure. In some arrangements, FIG. 5A is a top view of a portion 1A of the package structure 1 in FIG. 1 in accordance with some arrangements of the present disclosure.

In some arrangements, a center of the conductive pad 110 is misaligned with a center of a projection of the wires 50. In some arrangements, the conductive pad 110 partially overlaps the encapsulant 60 from a top view perspective. In some arrangements, the conductive pad 110 partially overlaps the air gap G3 from a top view perspective. In some arrangements, the wires 50 have different densities in different regions of the package structure. For example, the wires 50 in a region R1 have a density greater than that of the wires 50 in a region R2. The region R1 may overlap the conductive pad 110 from a top view perspective, and the region R2 may be free from overlapping the conductive pad 110 from a top view perspective.

In some arrangements, the extension 601 of the encapsulant 60 surrounds the wires 50. In some arrangements, the wires 501 are encapsulated or covered by the extension 601 of the encapsulant 60. In some arrangements, the wires 504 are partially encapsulated or covered by the extension 601 of the encapsulant 60. In some arrangements, the wires 503 overlap the conductive pad 110 from a top view perspective. In some arrangements, at least two wires (e.g., one of the wires 501 and one of the wires 504) directly contact each other. In some arrangements, the conductive pad 110 has a rectangular shape as shown in FIG. 5A. Please be noted that the shape of the conductive pad 110 may vary according to actual applications and is not limited thereto.

FIG. 5B is a top view of a portion of a package structure in accordance with some arrangements of the present disclosure. In some arrangements, FIG. 5B is a top view of a portion 1A of the package structure 1 in FIG. 1 in accordance with some arrangements of the present disclosure.

In some arrangements, the wires 50 have different densities in different regions of the package structure. For example, the wires 50 in a region R1a have a density greater than that of the wires 50 in a region R1b. For example, the wires 50 in the region R1a have a density greater than that of the wires 50 in the region R2. In some arrangements, the regions R1a and R1b both overlap the conductive pad 110 from a top view perspective, and the region R2 may be free from overlapping the conductive pad 110 from a top view perspective. In some arrangements, the conductive pad 110 has an elliptical shape as shown in FIG. 5B. Please be noted that the shape of the conductive pad 110 may vary according to actual applications and is not limited thereto.

FIG. 5C is a top view of a portion of a package structure in accordance with some arrangements of the present disclosure. In some arrangements, FIG. 5C is a top view of a portion 1A of the package structure 1 in FIG. 1 in accordance with some arrangements of the present disclosure.

In some arrangements, a center of the conductive pad 110 is substantially aligned with a center of a projection of the wires 50. In some arrangements, the wires 50 have different densities in different regions of the package structure. For example, the wires 50 in a region R1c have a density greater than that of the wires 50 in a region R1p. For example, the wires 50 in the region R1c have a density greater than that of the wires 50 in the region R2. In some arrangements, the regions R1c and R1p both overlap the conductive pad 110 from a top view perspective, and the region R2 may be free from overlapping the conductive pad 110 from a top view perspective. In some arrangements, the region R1c corresponds to a center region of the conductive pad 110, and the region R1p corresponds to a peripheral region of the conductive pad 110.

According to some arrangements of the present disclosure, with the design of the recess accommodating the wires that electrically connect the wiring structure and the conductive elements, the size and the shape of the conductive pad (e.g., the conductive pad 110) can vary according to actual applications. Therefore, the routing flexibility is increased.

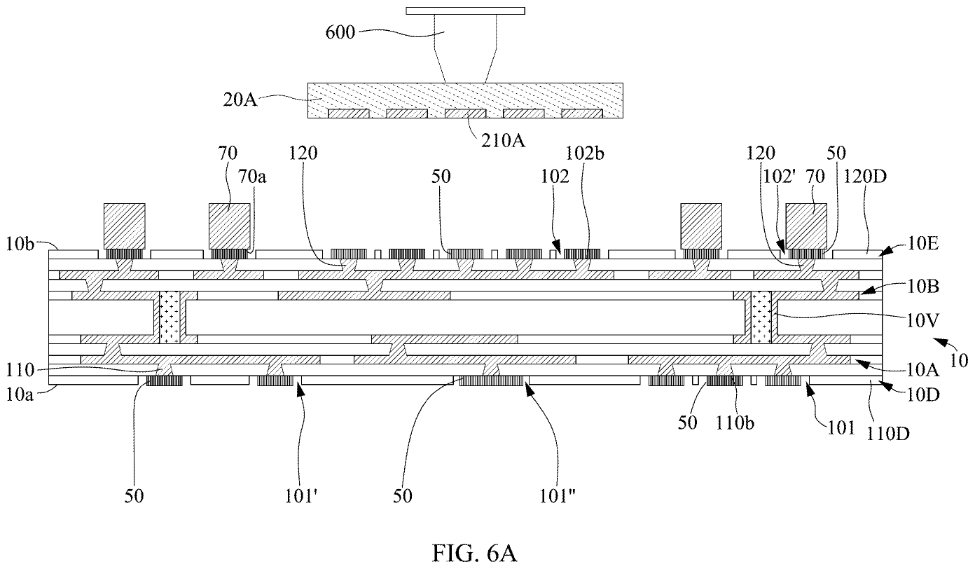

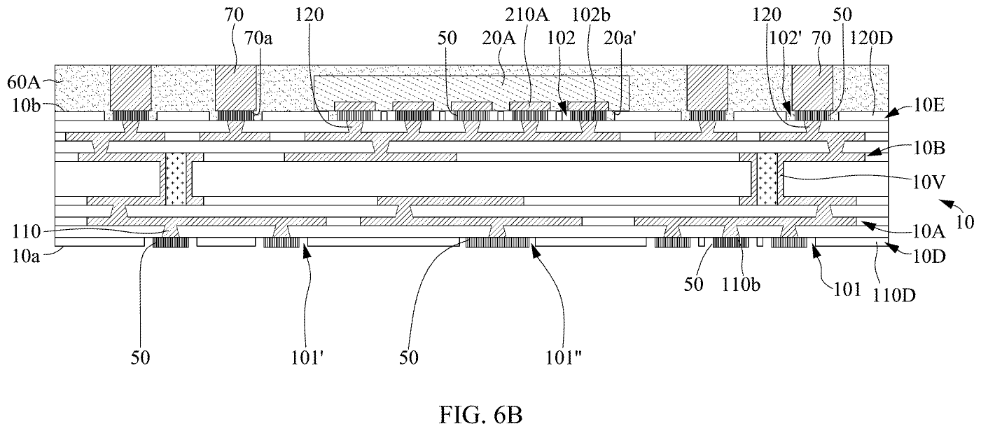

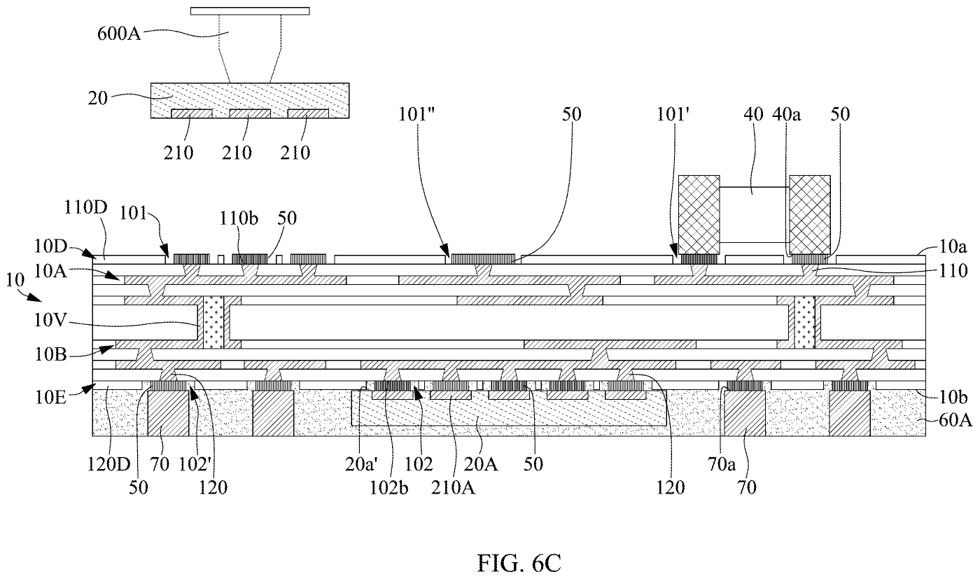

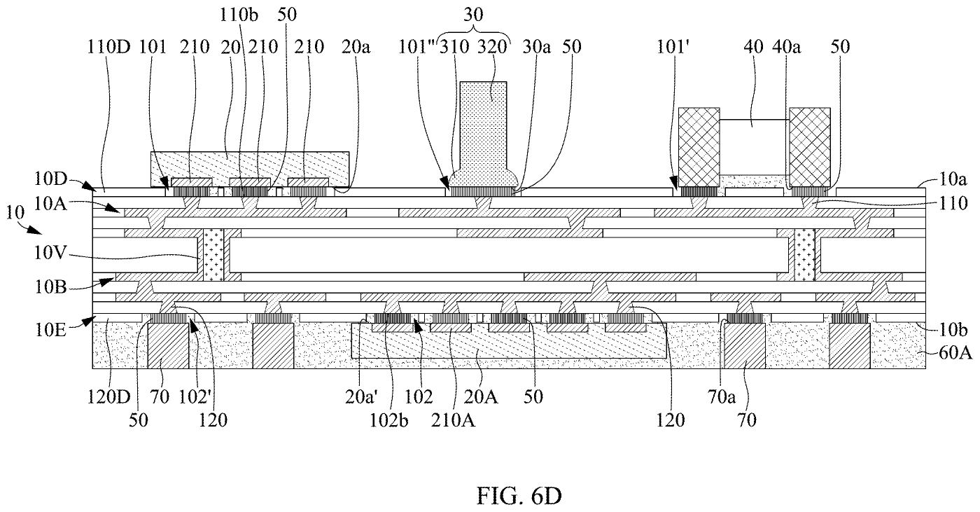

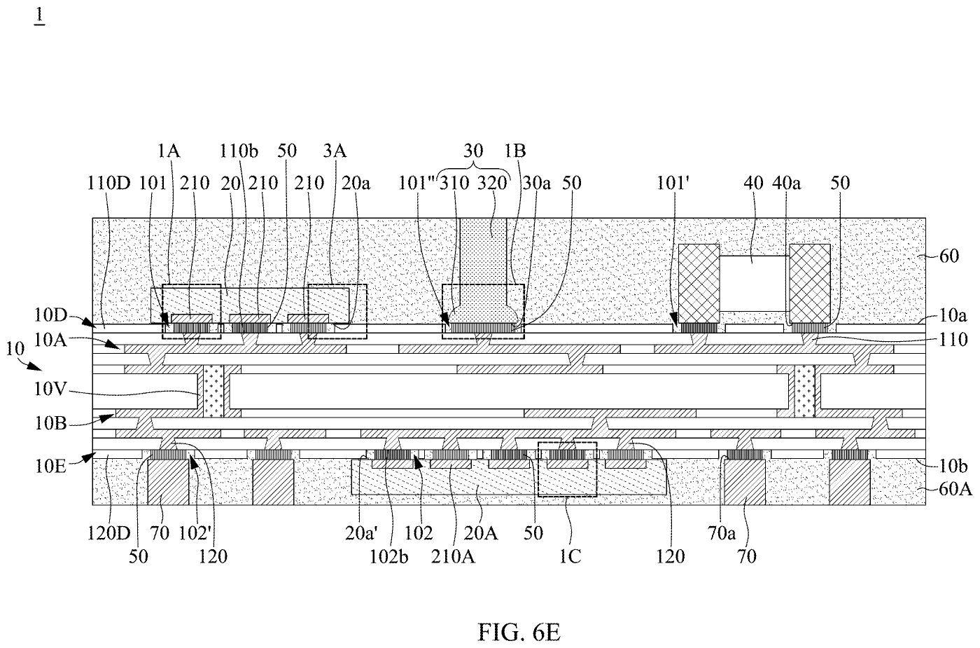

FIG. 6A, FIG. 6B, FIG. 6C, FIG. 6D, and FIG. 6E illustrate various stages of an example of a method for manufacturing a package structure in accordance with some arrangements of the present disclosure.

Referring to FIG. 6A, a wiring structure 10 having recesses 101, 101′, and 101″ recessed from a surface 10a and recesses 102 and 102′ recessed from a surface 10b may be provided, and wires 50 may be formed in the recesses 101, 101′, 101″, 102, and 102′. Conductive pillars 70 may be bonded to the wires 50. An electronic component 20A including conductive pads 210A may be provided. In some arrangements, a bonding operation may be performed on the electronic component 20A and the wiring structure 10. The electronic component 20A may be bonded to the surface 10b of the wiring structure 10.

In some arrangements, a bonding apparatus 600 (e.g., a bond head) may be used to push the electronic component 20A toward the wiring structure 10 to guide the conductive pads 210A to contact the wires 50. In some arrangements, in the bonding operation, a heating operation may be performed to sinter the wire 50. In some arrangements, the heating operation may be performed under a temperature lower than a melting point of a soldering material. In some arrangements, the heating operation may be performed under a temperature lower than a temperature (e.g., about 260° C.) of a reflow operation for soldering materials. In some arrangements, the heating operation may be performed under a temperature equal to or lower than about 150° C. In some arrangements, the heating operation may be performed under a temperature equal to or lower than about 100° C.

Referring to FIG. 6B, after the electronic component 20A is bonded to the surface 10b of the wiring structure 10, the conductive pillars 70, the electronic component 20A, and the wires 50 may be encapsulated by an encapsulant 60A.

Referring to FIG. 6C, the structure illustrated in FIG. 6B may be flipped over, an electronic component 40 may be bonded to the wires 50 at the surface 10a of the wiring structure 10. An electronic component 20 including conductive pads 210 may be provided. In some arrangements, a bonding operation may be performed on the electronic component 20 and the wiring structure 10. The electronic component 20 may be bonded to the surface 10a of the wiring structure 10.

In some arrangements, a bonding apparatus 600A (e.g., a bond head) may be used to push the electronic component 20 toward the wiring structure 10 to guide the conductive pads 210 to contact the wires 50. In some arrangements, in the bonding operation, a heating operation may be performed to sinter the wire 50. In some arrangements, the heating operation may be performed under a temperature lower than a melting point of a soldering material. In some arrangements, the heating operation may be performed under a temperature lower than a temperature (e.g., about 260° C.) of a reflow operation for soldering materials. In some arrangements, the heating operation may be performed under a temperature equal to or lower than about 150° C. In some arrangements, the heating operation may be performed under a temperature equal to or lower than about 100° C.

Referring to FIG. 6D, a bonding wire element 30 may be bonded to the wires 50 at the surface 10a of the wiring structure 10. A ball bond 310 of the bonding wire element 30 may be bonded to the wires 50.

Referring to FIG. 6E, after the electronic component 20 is bonded to the surface 10a of the wiring structure 10, the electronic component 20 and 40, the bonding wire element 30, and the wires 50 may be encapsulated by an encapsulant 60. As such, the package structure 1 illustrated in FIG. 1 is formed.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of said numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to #1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some arrangements, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific arrangements thereof, these descriptions and illustrations do not limit the present disclosure. It can be clearly understood by those skilled in the art that various changes may be made, and equivalent components may be substituted within the arrangements without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and the like. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. A package structure, comprising:
a wiring structure having a first recess recessed from a first surface of the wiring structure;
a first element disposed over the first surface of the wiring structure; and
a plurality of first wires disposed in the first recess and extending in a direction from the wiring structure to the first element, wherein the first wires are configured to reduce an inclination of the first element with respect to the first surface of the wiring structure.

2. The package structure as claimed in claim 1, wherein at least one of the first wires comprises a curved portion contacting the first element.

3. The package structure as claimed in claim 1, wherein a distance between the first surface of the wiring structure and a surface of the first element is less than a depth of the first recess.

4. The package structure as claimed in claim 1, further comprising an encapsulant encapsulating the first element and the first wires and extending into the first recess, wherein the encapsulant is a monolithic layer.

5. The package structure as claimed in claim 4, wherein an extension of the encapsulant extends between the first wires.

6. The package structure as claimed in claim 4, wherein the encapsulant comprises a filler disposed adjacent to an inner sidewall of the first recess.

7. The package structure as claimed in claim 6, wherein the filler contacts a sidewall of the first wires.

8. The package structure as claimed in claim 4, wherein the encapsulant comprises a first filler disposed in the first recess and a second filler disposed outside of the first recess, and a size of the first filler is less than a size of the second filler.

9. The package structure as claimed in claim 4, wherein the encapsulant comprises a filler disposed in the first recess, and a size of the filler is less than a distance of a gap between the first surface of the wiring structure and a surface of the first element.

10. The package structure as claimed in claim 4, wherein a first one of the first wires contacts the encapsulant, and a second one of the first wires is spaced apart from the encapsulant by an air gap.

11. The package structure as claimed in claim 10, wherein a thickness of the encapsulant decreases in a direction from the first one of the first wires toward the second one of the first wires.

12. The package structure as claimed in claim 10, wherein a third one of the first wires is between the first one and the second one of the first wires, and the third one of the first wires comprises a first portion contacting the encapsulant and a second portion exposed to the air gap.

13. A package structure, comprising:
a wiring structure;
a wire bond connection disposed over the wiring structure; and
a plurality of wires connecting the wiring structure to a first surface of the wire bond connection and configured to define a non-planar profile of the first surface of the wire bond connection.

14. The package structure as claimed in claim 13, wherein the first surface of the wire bond connection comprises a wavy surface portion.

15. The package structure as claimed in claim 13, wherein the wire bond connection comprises a ball bond having the non-planar profile.

16. The package structure as claimed in claim 15, wherein the wire bond connection further comprise a conductive wire connected to the wires through the ball bond.

17. The package structure as claimed in claim 13, wherein the plurality of wires comprise a first wire having a curved end contacting the wire bond connection.

18. The package structure as claimed in claim 17, wherein the plurality of wires further comprise a second wire inserted into the wire bond connection.

19. The package structure as claimed in claim 13, wherein the non-planar profile is inclined with respect to a surface of the wiring structure.

20. The package structure as claimed in claim 13, wherein the wire bond connection comprises a shielding element.
